(19) United States
(12) Patent Application Publication
(10) Pub. No.: US 2012/0235693 A1
(43) Pub. Date: Sep. 20, 2012

(54) Ceramic Crack Inspection

(76) Inventor: Hong Feng, Newport Coast, CA (US)

(21) Appl. No.: 13/052,080

(22) Filed: Mar. 20, 2011

(51) Int. Cl. G01R 27/08

(52) U.S. Cl. 324/693

(57) ABSTRACT

A method and apparatus for non-destructive inspection including detection, quantification, and location of a surface or subsurface crack in a body made of advanced technical ceramics. The method and apparatus can detect all cracks in a ceramic body, including microscopic cracks, with a high sensitivity, accuracy and reliability, by measuring changes in electrical resistances through a plurality pairs of electrodes affixed on surfaces of the ceramic body. The extent of the cracks can be quantified and expressed as numerical data, and the location of the cracks can be identified. An automated inspection process enables a convenient, real-time, cost-effective crack inspection.

### CROSS-REFERENCE TO RELATED APPLICATIONS

Not Applicable

### STATEMENT REGARDING FEDERALLY SPONSORED RESEARCH OR DEVELOPMENT

Not Applicable

### REFERENCE TO SEQUENCE LISTING, A TABLE, OR A COMPUTER PROGRAM LISTING COMPACT DISC APPENDIX

Not Applicable

### BACKGROUND OF THE INVENTION

1. Field of the Invention

The present invention relates to a method and an apparatus for inspecting crack in a manufactured body made of advanced technical ceramics, such as a ceramic ballistic armor plate.

2. Description of the Prior Art

Advanced technical ceramics are valued for their hardness, strength, wear resistance, thermal and chemical stability, light weight and abrasion resistance, and hence find wide use in such applications as ballistic protective armor systems, high-performance engines, semiconductor equipment, and wear components of equipment in oil, gas, and mining operations. However, due to the brittle nature, advanced ceramics are subject to cracking upon impact. Cracks, including invisible microscopic cracks, significantly degrade ceramic performance. Therefore, a method for inspecting cracks in ceramics is highly desired.

Heretofore, the following techniques have been known as processes for detecting a crack in a ceramic body. One is the dye penetrant inspection. After a penetrable liquid containing a coloring matter penetrates fine cracks present in a ceramic body, excess liquid attached to the surface of the ceramic body is washed off. As a result, no coloring matter remains attached onto a portion of the ceramic body free from cracks, whereas the coloring matter remains on any portions containing such cracks. Further, a fluorescent paint may be used instead of the coloring matter. In this case, ultraviolet rays are irradiated upon the ceramic body in a dark chamber, and the fluorescent paint remained on cracks in the ceramic body will emit light. Therefore, the dye-penetrant method, weather using a coloring matter or a fluorescent paint, detects cracks by visual inspection, and as a result, the detecting ability depends upon the skill of inspecting individuals, whereby a fine crack may be overlooked. Further, visual inspection hinders automation of consecutive steps, and the result of the inspection is difficult to express as numerical data for crack quantification. In addition, this method cannot detect internal subsurface cracks that are not exposed to the surface. It is time consuming to inspect a large ceramic body. Some ceramic bodies are embedded in a system during their usage, such as a ceramic plate in an armor system, and thus such a vision-based inspection cannot be easily performed.

Non-destructive evaluation (NDE) techniques including ultrasonic, X-ray tomography, radiography, and acoustic emission have potential to detect cracks in ceramics. However, these NDE methods require relatively complex, expensive, and high-maintenance equipment, along with trained personnel to perform the inspection and analyze the results, making the inspection costly and time-consuming. In addition they often have difficulties to detect microscopic cracks. The X-ray, along with radiography, also raises concerns of radiation safety. The acoustic emission method detects cracks only while they are actually forming, and thus requires continuous monitoring that is often unfeasible.

Other techniques for detection of cracks in ceramics are based on electrical measurement. U.S. Pat. No. 5,969,532 is a method for detecting cracks in a ceramic substrate by immersing one face of the ceramic substrate in a conductive liquid and measuring resistance between the conductive liquid and an electrode attached on the other surface of the ceramic substrate. If a crack exists in the ceramic, the conductive liquid would fill in the crack and reduce the resistance between the two surfaces of the ceramic substrate. This method is obviously cumbersome to apply during the usage of a ceramic body. In addition, a crack must propagate through the ceramic body in order to be detected. U.S. Pat. No. 7,180,302 is a method for detecting cracks in a ceramic plate in an armor system by depositing an electrical circuit on the surface of a ceramic plate and measuring the resistance of the circuit. A crack on the plate will break the electrical conductivity of the circuit. Obviously this method cannot detect subsurface cracks on a ceramic body. The sensitivity of this method is limited by the bonding condition between the circuit and the ceramic surface. More importantly, most advanced technical ceramics (including those used in armor systems) are electrically conductive or semi-conductive. Therefore, a layer of electrically non-conductive coating must be applied on the ceramic surface before the electrical circuit is deposited. This insulation layer not only increases the cost, but also reduces the sensitivity of this method to ceramic cracks.

### BRIEF SUMMARY OF THE INVENTION

It is the objective of the present invention to solve the above-mentioned problems and to provide a reliable, low-cost, and easy-to-operate method, together with an apparatus, for detecting, quantifying, and locating cracks, including microscopic cracks, in a body made of advanced technical ceramics, irrespective of the operator's skill.

The method takes advantage of electrical conductivity in advanced ceramics including, but not limited to, those being used in ballistic armor systems. A crack will reduce the electrical conductivity, and thus increase electrical resistivity of a ceramic body. Therefore, one can detect the crack by affixing a pair of electrodes on one or more surfaces of the ceramic body and measure electrical resistance of the body through the pair of electrodes. An increase in the electrical resistance from a previously measured reference value indicates the presence of a crack or cracks. The amount of increase can be used to quantify the extent of the crack or cracks.

In exemplary embodiments, the ceramic body is shaped as a rectangular tile, and a pair of electrodes is affixed at two locations on two opposite side surfaces of the tile. In order to increase the sensitivity to microscopic cracks, a plurality of electrode pairs are distributed on all four side surfaces of the ceramic tile. By sequentially measuring the resistance through each of the electrode pairs, any crack at an unknown location of the ceramic body, whether on surface or in subsurface, can be detected. The location of the crack or cracks can be determined by identifying the pairs of electrodes that experienced changes in their electrical resistance values.

Further, an automated inspection method, together with an apparatus, enables a real-time cost-effective inspection of a ceramic body. Each of the plurality of electrode pairs affixed onto the ceramic body is wired to a resistance measurement circuit, which contains a microprocessor, a selector, a memory chip, a power supply, and a display. The microprocessor controls the selector to sequentially measure resistance through each of the electrode pairs, judges the presence or absence of a crack, and quantifies the crack extent, and identifies the crack location based on the comparison of the measured and the reference resistance values for each pair of the electrodes, and displays the results in the display.

Further, the apparatus for the automated inspection is separated into two units—the sensor unit on the ceramic body that contains the electrodes, the microprocessor, the selector, and the memory and a keychain-size device that contains the power supply and the display. An operator simply plugs the keychain-size device into the sensor unit on the ceramic body through a connector or wirelessly to initiate the automated inspection and reads the results through the display. The microprocessor and the memory can also been moved to the keychain-size device, depending on the specific application. The display can be an LCD screen to display the inspection results expressed in numerical data, or an LED light to display yes (cracked) in red or no (no crack) in green, for example.

The present invention offers obvious advantages over the prior art, as summarized below:
1. The method detects a crack or cracks on a surface or sub-surface of a ceramic body;
2. The method is sensitive to microscopic cracks;
3. The results can be expressed in numerical data for quantitative crack assessment;
4. The results can be simply expressed as yes (cracked) or no (no crack), if desired;
5. The method is simple and reliable;
6. The apparatus is compact and the cost is low;
7. The inspection is easy to perform, requires no skills of the operator;
8. The inspection is safe for an operator to perform.
9. The automated inspection method further simplifies the operation;
10. The automated inspection is rapid, obtaining results in a second;
11. The automated inspection can be performed even when the ceramic body is embedded in a system and thus invisible, as long as electrodes are pre-affixed on the ceramic body;
12. The apparatus consumes little power;
13. In the automated inspection apparatus that is separated into the two units, the keychain-size device that contains the power supply can be made disposable.
14. The apparatus requires no maintenance.

The invention may now be visualized by turning to the following drawings wherein like elements are referenced by like numerals.

### BRIEF DESCRIPTION OF THE SEVERAL VIEWS OF THE DRAWING

FIG. 1 is a view schematically showing a ceramic body with electrodes affixed at two locations on two opposite surfaces to measure electrical resistivity of the ceramic body.

FIG. 2 is a view for schematically illustrating the principle by which a crack is detected according to the present invention, i.e., a crack in a ceramic body narrowing the pathway of electrical current and thus reducing conductivity and increasing electrical resistivity.

FIG. 3 is a view schematically showing placement of a plurality of pairs of electrodes on a ceramic body to detect and locate a crack or cracks.

FIG. 4 is a view schematically showing an example of an inspection apparatus for automated, convenient inspection, which consists of a sensor unit on a ceramic body and a keychain-size device for initiation the inspection.

The illustrated embodiments of the invention now having been depicted in the above drawings, turn to the following detailed description of the invention and its various embodiments.

### DETAILED DESCRIPTION OF THE INVENTION

The basic process of inspecting a crack or cracks on a ceramic body according to the present invention is characterized in that (1) a pair of electrodes are affixed at two locations on one or more surfaces of a ceramic body; (2) electrical resistance of the ceramic body is measured through the pair of electrodes; and (3) the presence or absence of cracks in this portion of the ceramic body, as well as extent of the cracks, is judged based on a comparison result between the measured electrical resistance value and a reference value.

In order to increase the sensitivity to microscopic cracks and to further locate the cracks, (4) a plurality of electrode pairs are affixed on one or more surfaces of a ceramic body; (5) the electrical resistance is measured through each pair of the electrodes; (6) the presence or absence of cracks, as well as extent of the cracks, is judged based on a comparison result between the measured electrical resistance and a reference value for each pair of the electrodes; (7) locations of the cracks are approximately estimated by identifying the pairs of electrons that experienced changes in the measured resistance values; (8) the above inspection process can be automated by wiring each pair of the electrodes to a circuit, wherein a microprocessor controls the process of sequential measurement of resistance through each pair of the electrodes and judges the existence, extent, and location of cracks; and (9) the automated inspection process can be initiated by plugging a small keychain-size device, which contains a power supply, into the circuit.

A detailed description is as follows:

In the process of detecting a crack or cracks of a ceramic body according to the present invention, a pair of electrodes having high electrical conductivity is affixed at two locations on one or more surfaces of the ceramic body. As ceramic materials of the bodies to which the present invention is applicable, all of advanced technical ceramics that have electrical conductivity and/or semiconductivity including silicon carbide, boron carbide, and titanium diboride, as well as advanced technical ceramics embedded with carbon nanotube or carbon nano fibers, may be cited. As materials for the electrodes used in this invention, materials with high electrical conductivity such as copper and silver may be cited. The electrodes can also be painted onto a ceramic surface using electrically conductive paint.

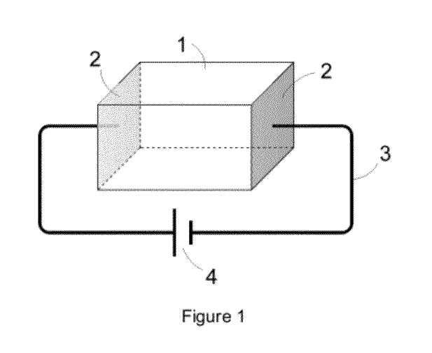

FIG. 1 is a view schematically showing a ceramic body with a pair of electrodes affixed at two locations on two opposite surfaces to measure electrical conductivity of the ceramic body. In FIG. 1, the ceramic body is denoted by numeral 1 and the electrode by numeral 2. Numeral 3 is an electrical wire and numeral 4 an electrical power source such as a battery. The conductivity of the ceramic body is represented by an electrical resistance value that is computed on the basis of the measured electrical current and voltage.

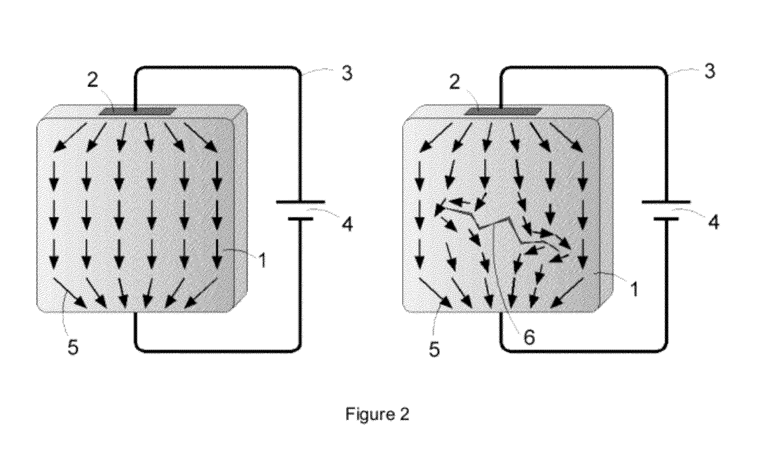

FIG. 2 is a view for schematically illustrating the principle by which a crack in ceramic body 1 is detected according to the present invention. In FIG. 2, numeral 5 denotes electrical current, while numeral 6 represents a crack on ceramic body 1. Crack 6, on the surface or in the subsurface of ceramic body 1, will narrow the pathway of electrical current 5, and thus reduce electrical conductivity. Therefore, by affixing a pair of electrodes 2 at two locations on two opposite surfaces of the ceramic body 1, the conductivity of the body can be measured by computing electrical resistance as explained in FIG. 1.

The measured electrical resistance value is then compared with a reference value. The reference value is a resistance value previously measured on the same ceramic body through the same pair of electrodes before the crack was initiated, or a standard value of the same ceramic material involving no crack. If the measured resistance is larger than the reference value, it is judged that a crack or cracks exists in the ceramic body. The amount of change in the resistance value from the reference value is used to quantify the crack extent. On the contrary, it is judged that no crack exists in the ceramic body if the difference between the measured and the reference resistance values is below a threshold. Therefore, by measuring the electrical resistance of the ceramic body, whether there is a crack or not can be grasped objectively and quantitatively.

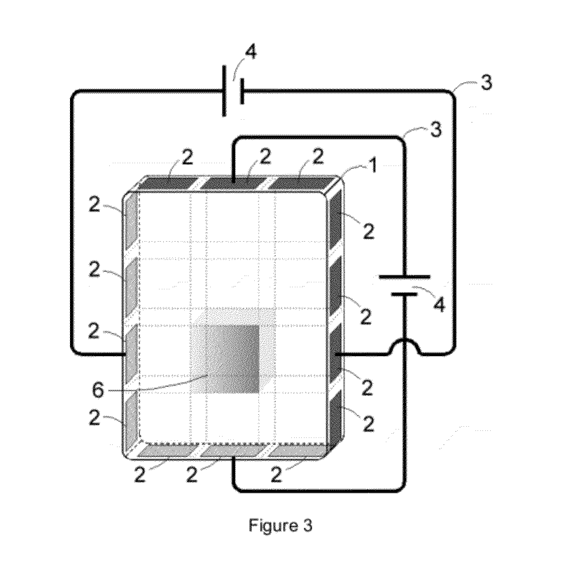

The principle of the method of the present invention as described in FIG. 2 requires that one pair of electrodes be affixed at two locations on two opposite faces of a ceramic body. However, for inspecting a large ceramic body with a microscopic crack at an unknown location, it is preferable that a plurality of pairs of small electrodes, rather than a single pair of large electrodes, be distributed on all opposite faces, as schematically illustrated in FIG. 3. These electrodes divide the entire ceramic body into grids. To a large extent, the electrical resistance value measured through one of the electrode pairs represents the conductivity of the rectangular prism portion of the ceramic body between the pair of the electrodes located in opposite surfaces of the ceramic body. Therefore, the entire ceramic body is inspected by measuring, in sequence, the electrical resistance value through each pairs of the electrodes. The measured resistance value through each pair of the electrodes is compared with its own reference value. By comparing all the resistance values with their respective reference values, the presence or absence of a crack is judged. If none of the resistance values measured through the electrode pairs experiences any change from the reference value, it is judged that no crack exists in the ceramic body. Otherwise, it is judged that a crack or cracks exists. If a crack or cracks is detected, its extent is further assessed by the amount of resistance change from the reference value. Further, the crack location is approximately identified. As an example, FIG. 3 highlights two pairs of electrodes, one pair affixed on the two opposite vertical surfaces, while the other pair on the two opposite horizontal surfaces. If electrical resistance values measured through these two pairs of electrodes were increased from their respective reference values, while resistance values measured through other pairs of electrodes did not change, it would be judged that a crack or cracks exists and is approximately located in the intersection of the two rectangular prisms between these two pairs of electrodes, i.e., grid 6.

There are two advantages of using a plurality pairs of small electrodes placed next to each other as shown in FIG. 3, rather than a single pair of large electrodes. First, the small electrodes divided the ceramic body into small grids, and thus the conductivity measurement becomes more sensitive to microscopic cracks. Another advantage of using a plurality pairs of small electrodes is the ability to locate cracks.

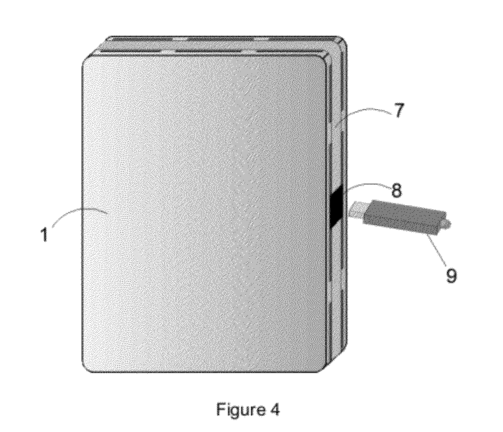

FIG. 4 is a view schematically showing an example of an apparatus for automated inspection of a ceramic body. A plurality of electrode pairs is affixed on the side surfaces of ceramic body 1 and each pair is individually wired to a resistance measurement circuit 8, which is placed on ceramic body 1. All such wires can be built in a thin, flexible tape denoted by numeral 7. Inspection of ceramic body 1 is initiated by plugging into circuit 8 a small keychain-size device denoted by numeral 9. A microprocessor, located either in circuit 8 on ceramic body 1 or in keychain-size device 9, controls a selector in circuit 8 to sequentially measure electrical resistance through each of the plurality pairs of the electrodes. A memory chip, located either in circuit 8 1 or keychain-size device 9, stores reference resistance values and measured resistance values. A power supply and a display, which is either an LCD screen or an LED light, are built in keychain-size device 9. The unit that contains all the electrode pairs 2, wires 7, and resistance measurement circuit 8 is referred to as the sensor unit.

Once keychain-size device 9 is plugged into circuit 8 through a connector or wirelessly, the microprocessor starts to control the selector in circuit 8 to measure resistance through each pair of the electrodes in sequence and compares the measured electrical resistance value with a reference value stored in the memory. Based on the comparison for each of the electrode pairs, the microprocessor judges the presence or absence of a crack or cracks on ceramic body 1. If a crack or cracks is detected, the microprocessor assesses the crack extent according to embedded algorithms and further identifies the crack location. The inspection results can be expressed as numerical numbers and displayed on the LCD screen. If a “yes” or “no” result is desired, an LED light (as shown in FIG. 4) can replace the LCD screen to simply turn the light to a color such as red to indicate “yes—crack detected” or a different color such as green to indicate “no—no crack detected”.

Depending on the usage of a ceramic body, a variety of alternative designs can be made for the convenience of inspection. For example, the microprocessor can be placed in circuit 8 or keychain-size device 9, and the memory can be placed in circuit 8 or keychain-size device 9. Instead of plugging in through a connector, a wireless connection can be established between circuit 8 and keychain-size device 9. Another alternative design is to eliminate handheld 9, by moving all the components including the power supply and the display to circuit 8 on ceramic body 1.

An example is a ceramic tile used in a personnel ballistic protective armor system. Ceramic cracks degrade the ballistic performance of the armor system and thus a convenient inspection method is needed. For this particular usage, a battery power supply and an LED light are built into the keychain-size device, separated from the resistance measurement circuit that is built on the ceramic tile. An operator conveniently plugs the keychain-size device into the circuit to inspect the ceramic tile at anytime, without taking the tile out of the armor system. The inspection results are displayed in real time by the LED light, requiring no judgment of the operator that is often subjective. The battery in the sensor key can easily supply power for hundreds of times of inspection. The low-cost sensor key can be disposed of once the battery power is consumed.

The automated inspection method for advanced technical ceramics offers significant advantages over the prior art. The inspection is high-speed and quantified results are displayed in real time. No post data processing is needed. The apparatus is simple, requiring neither expensive components nor cumbersome maintenance. The operation is straightforward and no training of the operator is required. The cost of the inspection including the apparatus and the operation is low.

Many alterations and modifications may be made by those having ordinary skill in the art without departing from the spirit and scope of the invention. Therefore, it must be understood that the illustrated embodiment has been set forth only for the purposes of example and that it should not be taken as limiting the invention as defined by the following claims.

The words used in this specification to describe the invention and its various embodiments are to be understood not only in the sense of their commonly defined meanings, but to include by special definition in this specification structure, material or acts beyond the scope of the commonly defined meanings Thus if an element can be understood in the context of this specification as including more than one meaning, then its use in a claim must be understood as being generic to all possible meanings supported by the specification and by the word itself.

The definitions of the words or elements of the following claims are, therefore, defined in this specification to include not only the combination of elements which are literally set forth, but all equivalent structure, material or acts for performing substantially the same function in substantially the same way to obtain substantially the same result. In this sense it is therefore contemplated that an equivalent substitution of two or more elements may be made for any one of the elements in the claims below or that a single element may be substituted for two or more elements in a claim.

Insubstantial changes from the claimed subject matter as viewed by a person with ordinary skill in the art, now known or later devised, are expressly contemplated as being equivalently within the scope of the claims. Therefore, obvious substitutions now or later known to one with ordinary skill in the art are defined to be within the scope of the defined elements.

The claims are thus to be understood to include what is specifically illustrated and described above, what is conceptually equivalent, what can be obviously substituted and also what essentially incorporates the essential idea of the invention.

1. A method of detecting a crack in a ceramic body including surfaces and having electrical conductivity and/or semiconductivity, comprising the steps of:
affixing one or a plurality of electrode pairs on one or more surfaces of said ceramic body,
measuring electrical resistance through each pair of said electrode pairs,
comparing said measured resistance value with a respective reference resistance value that is either a previously measured resistance value at said electrode pair or a standard value of the same material involving no crack, and
determining the presence or absence of a crack based on said comparison between said measured and said reference resistance values, for each pair of said electrode pairs,
wherein an increase of resistance over said reference value in one or more of said plurality of electrode pairs indicates the presence of a crack.

2. The method of claim 1, wherein the extent of said crack in said ceramic body is quantified based on the amount of the resistance increase at one or more of said plurality of electrode pairs.

3. The method of claim 1, wherein the location of said crack in said ceramic body is identified by the relative location of said one or more electrode pairs whose measured resistance values increased over their respective reference values.

4. An automated method of detecting, quantifying, and locating a crack in a ceramic body including surfaces and having electrical conductivity and/or semiconductivity, comprising the steps of:
affixing a plurality of electrode pairs on one or more surfaces of said ceramic body,
wiring each of said plurality of electrode pairs to an electrical resistance measurement circuit,
connecting a power supply to the said resistance measurement circuit,
connecting a visual display to said resistance measurement circuit,
connecting a memory to said resistance measurement circuit, wherein said memory stores reference resistance values for all of said plurality of electrode pairs,
connecting a selector to said resistance measurement circuit,
connecting a microprocessor to said resistance measurement circuit,
initiating an inspection process wherein said microprocessor controls the selector to sequentially measure resistance through each of said plurality of electrode pairs,
wherein said microprocessor compares said measured resistance value with a respective reference resistance value stored in said memory, said reference resistance value comprising either a previously measured resistance value at said electrode pair or a standard value of the same material involving no crack,
wherein said microprocessor determines the presence or absence of a crack based on said comparison between said measured and said reference resistance values, for each of the plurality of electrode pairs,
wherein an increase of resistance over a reference value in one or more of said plurality of electrode pairs indicates the presence of a crack,
wherein said microprocessor quantifies the extent of said crack by producing numerical data based on the amount of the resistance increase at one or more of said plurality of electrode pairs,
wherein said microprocessor locates said crack by identifying the electrode pairs whose measured resistance values increased over their respective reference values,
wherein said microprocessor displays the results of crack presence, extent, and location in said visual display.

5. The method of claim 4 wherein said visual display comprises an LCD screen or an LED light.

6. The method of claim 4 wherein said visual display reports the results as numerical values.

7. The method of claim 4 wherein said visual display reports the results as a red light to indicate the presence of a crack or green light to indicate that no crack was detected.

8. The method of claim 4 wherein said visual display and said power supply are contained in a separate unit that is plugged into said resistance measurement circuit through a connector to initiate the automated inspection process and to display the inspection results in said visual display.

9. The method of claim 4 wherein said visual display and said power supply are contained in a separate unit that is wirelessly plugged into said resistance measurement circuit to initiate the automated inspection process and to display the inspection results in said visual display.

10. An apparatus for detecting, quantifying, and locating a crack in a ceramic body including surfaces and having electrical conductivity and/or semiconductivity, comprising:
One or a plurality of pairs of electrodes affixed on one or more surfaces of said ceramic body, and
a circuit for measuring electrical resistance through each said pair of electrodes, wherein said measured resistance is compared with a respective reference resistance value to detect a crack, quantify the extent of said crack, and identify the location of said crack.

11. The apparatus of claim 10 wherein said circuit comprises a multimeter.

12. A sensor unit for automated detection, quantification, and location of a crack in a ceramic body including surfaces and having electrical conductivity and/or semiconductivity, comprising:
a plurality of electrode pairs affixed on one or more surfaces of said ceramic body,
a plurality of electrical wires connecting each of said plurality of electrode pairs to a resistance measurement circuit that contains a memory for storing reference resistance values for all of said plurality of electrode pairs,
a power supply,
a visual display,
a selector, and
a microprocessor,
wherein said microprocessor controls said selector to sequentially measure resistance through each of said plurality of electrode pairs, judges crack existence, quantifies crack extent, and identifies crack location, based on comparison between measured resistance values and said stored reference resistance values according to a preprogrammed algorithm and expresses the results in numerical data and displays said data in said visual display.

13. The apparatus of claim 12 wherein said power supply and said visual display are packaged in a keychain-size device, separated from said sensor unit on said ceramic body, and said keychain-size device is plugged into said sensor unit on said ceramic body through a connector to initiate the automated inspection process and to display the results at said visual display.

14. The apparatus of claim 12 wherein said power supply and said visual display are packaged in a keychain-size device, separated from said sensor unit on said ceramic body, and said keychain-size device is wirelessly connected with said sensor unit on said ceramic body to initiate the automated inspection process and to display the results at said visual display.
